(19) United States
(12) Patent Application Publication
(10) Pub. No.: US 2026/0342209 A1
(43) Pub. Date: Oct. 29, 2026

(54) SWITCHING POWER SUPPLY AND POWER TRANSISTOR DRIVING CIRCUIT FOR SWITCHING POWER SUPPLY

(71) Applicant: Joulwatt Technology Co., Ltd., Hangzhou (CN)

(72) Inventors: Rengang CHEN, Hangzhou (CN); Siyun WANG, Hangzhou (CN); Aimin XU, Hangzhou (CN)

(21) Appl. No.: 19/659,841

(22) Filed: Apr. 27, 2026

(30) Foreign Application Priority Data
Apr. 28, 2025 (CN) 202510549481.X
Apr. 28, 2025 (CN) 202510550318.5

(51) Int. Cl. H02M 1/088; H02M 3/157; H02M 3/158; H03K 17/687

(52) U.S. Cl. CPC H02M 1/088; H02M 3/157; H02M 3/158; H03K 17/6871

(57) ABSTRACT

A switching power supply and a power transistor driving circuit are disclosed, comprising: a logic control module; a driving module generating a gate driving signal based on a conduction control signal and an off control signal generated by the logic control module, wherein the gate driving signal has a first slope greater than a second slope and the second slope during a conduction process; a voltage detection module, for detecting the voltage at the switching node upon turn-on of the power transistor, to obtain a voltage detection signal; a variable slope control module, for comparing the voltage detection signal with a reference voltage, and adjusting duration of the first slope in a next switching cycle based on a comparison result, so as to reduce a resonant voltage during a conduction process of the power transistor without increasing conduction loss, while balancing high-efficiency driving and circuit reliability.

### CROSS-REFERENCE TO RELATED APPLICATIONS

This present disclosure claims priority to a Chinese patent application No. 202510549481.X, filed on Apr. 28, 2025, and entitled "switching power supply and power transistor driving circuit for switching power supply", and a Chinese patent application No. 202510550318.5, filed on Apr. 28, 2025, and entitled "switching power supply and power transistor driving circuit for switching power supply", the entire contents of which are incorporated herein by reference, including the specification, claims, drawings and abstract.

### FIELD OF TECHNOLOGY

The present disclosure relates to the field of power supply technology, more specifically, to a switching power supply and a power transistor driving circuit for the switching power supply.

### BACKGROUND

Switching power supply controls the entire energy transfer process by feedback controlling the on and off time of the power transistor, achieving high-efficiency and wide range voltage conversion function. The design of the driving circuit is related to the on and off delay of the power transistor, as well as the current and voltage stress on the power transistor. A longer driving delay will cause significant switching losses and affect the transmission efficiency of the switching power supply system. The large dv/dt and di/dt generated when the driving circuit turns on or off the power transistor not only brings significant EMI noise interference to the reliability of the chip, but also poses significant challenges to the device's voltage resistance and overcurrent capability.

The traditional fixed slope driving circuit not only generates high EMI interference at the moments when the power transistors are turned on an off rapidly, but also increases the voltage stress of power transistors in high current application scenarios, seriously threatening the reliability of the devices. Slowing down the on and off speed will also cause efficiency loss and cannot adapt to high-efficiency applications. Therefore, the solution of fixed slope driving cannot solve the balance between switching loss and voltage stress caused by driving delay.

### SUMMARY OF THE DISCLOSURE

In view of the above problems, the purpose of the present disclosure is to provide a switching power supply and a power transistor driving circuit for the switching power supply, which can reduce the voltage stress of the rectifier transistor during the conduction process of the main power transistor of the switching power supply without increasing the conduction loss of the power transistor, and meanwhile balancing high-efficiency driving and circuit reliability.

In an aspect of the present disclosure, there is provided a power transistor driving circuit for a switching power supply, comprising: a logic control module, for generating a conduction control signal and an off control signal based on a received switch control signal; a driving module, for generating a gate driving signal for the power transistor based on the conduction control signal and the off control signal, wherein the gate driving signal has a first slope and a second slope which are time-dependent during the conduction process of the power transistor, and the first slope is greater than the second slope; a voltage detection module, for detecting the voltage at the switching node of the switching power supply when the power transistor is turned on, to obtain a voltage detection signal; a variable slope control module, for comparing the voltage detection signal with the reference voltage, and adjusting the duration of the first slope of the gate driving signal in the next switching cycle based on the comparison result.

Optionally, the variable slope control module is used to reduce the duration of the first slope in the next switching cycle when the voltage detection signal is greater than the reference voltage, and increase the duration of the first slope in the next switching cycle where the voltage detection signal is less than the reference voltage.

Optionally, the driving module comprises: a first pull-up transistor and a pull-down transistor connected between the high power rail voltage domain, wherein a common node of the first pull-up transistor and the pull-down transistor is connected to the gate driving signal; a second pull-up transistor, its first end is connected to the bootstrap voltage of the high power rail voltage domain and its second end is connected to the gate driving signal; a first buffer, its input terminal is connected to the conduction control signal and its output terminal is connected to the control terminal of the first pull-up transistor; a second buffer, its input terminal is connected to the off control signal and its output terminal is connected to the control terminal of the pull-down transistor; and a third buffer, its input terminal is connected to the fast conduction control signal output by the variable slope control module, and its output terminal is connected to the control terminal of the second pull-up transistor.

Optionally, the driving module is configured to turn on the first pull-up transistor and the second pull-up transistor during the first time period that the power transistor is turned on, so that the gate driving signal has the first slope, and turn on the first pull-up transistor and turn off the second pull-up transistor during the second time period that the power transistor is turned on, so that the gate driving signal has the second slope.

Optionally, the voltage detection module comprises: a voltage sampling unit connected to the voltage at the switching node for generating a voltage sampling signal representing the voltage at the switching node; and a peak detection unit, for generating the voltage detection signal representing the peak value of the voltage sampling signal based on the switch control signal.

Optionally, the peak detection unit comprises: a third capacitor, its first end is connected to the voltage sampling unit and its second end is connected to ground; the common node between the third capacitor and the voltage sampling unit is used to provide the voltage detection signal; a first switch, connected between the two ends of the second capacitor; and a single pulse module, used to output a single pulse signal with a fixed duration when the rising edge of the switch control signal is detected, wherein, the first switch is turned on when the single pulse signal is received, so that the second capacitor discharges to the ground through the first switch.

Optionally, the variable slope control module comprises: an inverting delay chain, for generating an inversed delay signal for the conduction control signal based on the received digital signal, wherein the invalid edge of the inversed delay signal is delayed by a set time relative to the valid edge of the conduction control signal; an OR gate, for performing OR logic operation on the conduction control signal and the inversed delay signal to generate the fast conduction control signal; a comparator, its negative input terminal is for receiving the voltage detection signal, its positive input terminal is for receiving the reference voltage, and its output terminal is for providing a comparison signal; a level shifting unit, for boosting the comparison signal in the low power rail voltage domain to the high power rail voltage domain; and an up-down counter, for performing addition and subtraction operations on the digital signal based on the pulse edges of the boosted comparison signal and the pulse edges of the switch control signal, so as to adjust the duration of the first slope of the gate driving signal by adjusting the delay time between the inversed delay signal and the conduction control signal.

Optionally, the comparator is a comparator with latch function, wherein, the comparator is used to compare the voltage detection signal with the reference voltage when the single pulse signal is in an active state, and to latch the comparison result when the single pulse signal is in an inactive state.

According to an aspect of the present application, there is provided a power transistor driving circuit for a switching power supply, comprising: a logic control module, for generating a conduction control signal and an off control signal based on the received switch control signals; a driving module, for generating a gate driving signal to drive the power transistor based on the conduction control signal and the off control signal, wherein the gate driving signal has a first slope and a second slope that are time-dependent during the process that the power transistor is turned off, and the first slope is greater than the second slope; a voltage detection module, used to detect the drain-source voltage of the power transistor when it is turned off, to obtain a voltage detection signal; and a variable slope control module, used to compare the voltage detection signal with a reference voltage and adjust the duration of the first slope of the gate driving signal in the next switching cycle based on the comparison result.

Optionally, the variable slope control module is used to reduce the duration of the first slope in the next switching cycle when the voltage detection signal is greater than the reference voltage, and increase the duration of the first slope in the next switching cycle where the voltage detection signal is less than the reference voltage.

Optionally, the driving module comprises: a pull-up transistor and a first pull-down transistor connected between the high power rail voltage domain, wherein a common node of the pull-up transistor and the first pull-down transistor is connected to the gate driving signal; a second pull-down transistor, its first terminal is connected to the gate driving signal and its second end connected to the switching node of the switching power supply; a first buffer, its input terminal is connected to the conduction control signal and an output terminal is connected to the control terminal of the pull-up transistor; a second buffer, its input end is connected to the off control signal and its output end is connected to the control terminal of the first pull-down transistor; and a third buffer, its input end is connected to the fast off control signal output by the variable slope control module, and its output end is connected to the control terminal of the second pull-down transistor.

Optionally, the driving module is configured to turn on the first pull-down transistor and the second pull-down transistor during the first time period that the power transistor is turned off, so that the gate driving signal has the first slope, and during the second time period that the power transistor is turned off, the first pull-down transistor is turned on and the second pull-down transistor is turned off, so that the gate driving signal has the second slope.

Optionally, the voltage detection module comprises: a voltage sampling unit, connected to the drain of the power transistor, used to generate a voltage sampling signal that represents the change slope of the drain-source voltage; and a peak detection unit, for generating the voltage detection signal that represents the peak value of the voltage sampling signal based on the switch control signal.

Optionally, the voltage sampling unit comprises: a first capacitor, its first end is connected to the drain of the power transistor; a first resistor, its first end is connected to the second end of the first capacitor and its second end connected to the ground; and a diode, its anode is connected to an intermediate node between the first capacitor and the first resistor, and its cathode is used for outputting the voltage sampling signal; the peak detection unit comprises: a second capacitor, its first end is connected to the voltage sampling unit and its second end is connected to the ground; the common node between the second capacitor and the voltage sampling unit is used to provide the voltage detection signal; a first switch, connected between the two ends of the second capacitor; and a single pulse module, for outputting a single pulse signal with a fixed duration when the falling edge of the switch control signal is detected, wherein, the first switch is turned on upon receiving the single pulse signal, so that the second capacitor discharges to the ground through the first switch.

Optionally, the variable slope control module comprises: an inverting delay chain, for generating the inversed delay signal of the off control signal based on the received digital signal, wherein the invalid edge of the inversed delay signal is delayed by a set time relative to the valid edge of the off control signal; AND gate, for performing AND logic operation on the off control signal and the inverted delay signal to generate the fast off control signal; a comparator, its negative input end is for receiving the voltage detection signal, its positive input end is for receiving the reference voltage, and its output terminal for providing a comparison signal; a level shifting unit, for boosting the comparison signal in the low power rail voltage domain to the high power rail voltage domain; and an up-down counter, for performing addition and subtraction operations on the digital signal based on the boosted comparison signal and the pulse edges of the switch control signal, in order to adjust the duration of the first slope of the gate driving signal by adjusting the delay time between the inversed delay signal and the off control signal.

Optionally, the comparator is a comparator with latch function, wherein, the comparator is used to compare the voltage detection signal with the reference voltage when the single pulse signal is in an active state, and to latch the comparison result when the single pulse signal is in an inactive state.

According to still aspect of the present disclosure, there is provided a switching power supply, comprising: a high side transistor, a low side transistor, and an inductor, wherein the high side transistor and the low side transistor are used to control the charging and discharging of the inductor to control the switching power supply to achieve power transmission; and the power transistor driving circuit, wherein the power transistor driving circuit is used to provide a gate driving signal to the high side transistor to control the on and off of the high side transistor.

According to still another aspect of the present disclosure, there is provided a switching power supply, comprising: multiple parallel power stage circuits, each power stage circuit comprising a high side transistor, a low side transistor, and an inductor, wherein the high side transistor and the low side transistor are used to control the charging and discharging of the inductor to control the switching power supply to achieve power transmission; and multiple power transistor driving circuits, each of which is used to provide a gate driving signal to the high side transistor of the corresponding power stage circuit to control the on and off of the high side transistor.

Optionally, the multiple power transistor driving circuits multiplex the voltage sampling unit in the voltage detection module in a time-division manner.

To sum up, the power transistor driving circuit of the embodiments of the present disclosure adopts a variable slope control method to generate the gate driving signal of the power transistor, and detects the waveform of the voltage at the switching node through a negative feedback loop during the conduction process of the power transistor. The fast slope duration of the gate driving signal in the next switching cycle is dynamically adjusted based on the detection result, so as to reduce the voltage stress of the low side transistor during the conduction process of the high side transistor without increasing the conduction loss of the power transistor, while balancing high-efficiency driving and circuit reliability.

### BRIEF DESCRIPTION OF THE DRAWINGS

The above and other objectives, features, and advantages of the present disclosure will become clearer through the following description of embodiments of the present disclosure with reference to the accompanying drawings; in the drawings:

FIG. 1 is a schematic circuit diagram of a power transistor driver circuit for a switching power supply.

FIG. 2 is a schematic structural diagram of a power transistor driving circuit for a switching power supply provided in the first embodiment of the present disclosure.

FIG. 3 is a schematic circuit diagram of the driving module provided in the first embodiment of the present disclosure.

FIG. 4 is a schematic circuit diagram of the voltage detection module provided in the first embodiment of the present disclosure.

FIG. 5 is a schematic circuit diagram of the variable slope control module provided in the first embodiment of the present disclosure.

FIG. 6 is a working waveform diagram of the inverting delay chain provided in the first embodiment of the present disclosure.

FIG. 7 is another working waveform diagram of the inverting delay chain provided in the first embodiment of the present disclosure.

FIG. 8 is the working waveform of the power transistor driving circuit provided in the first embodiment of the present disclosure.

FIG. 9 is a schematic diagram of the relationship between the fast slope conduction time and the peak voltage at the switching node of the power transistor driving circuit provided under different load currents by the first embodiment of the present disclosure.

FIG. 10 is a schematic structural diagram of the multi-phase power supply provided in the second embodiment of the present disclosure.

FIG. 11 is a schematic structural diagram of a power transistor driving circuit for the switching power supply provided in the third embodiment of the present disclosure.

FIG. 12 is a schematic circuit diagram of a driving module provided in the third embodiment of the present disclosure.

FIG. 13 is a schematic circuit diagram of a voltage detection module provided in the third embodiment of the present disclosure.

FIG. 14 is a schematic circuit diagram of a variable slope control module provided in the third embodiment of the present disclosure.

FIG. 15 is a working waveform diagram of the inverting delay chain provided by the third embodiment of the present disclosure.

FIG. 16 is another working waveform diagram of the inverting delay chain provided by the third embodiment of the present disclosure.

FIG. 17 is a working waveform of the power transistor driving circuit provided by the third embodiment of the present disclosure.

FIG. 18 is a schematic diagram of the relationship between the fast slope off duration of the power transistor driving circuit and the voltage of each node and the off loss of the high side transistor in the switching power supply provided by the third embodiment of the present disclosure.

FIG. 19 is a schematic structural diagram of a multi-phase power supply provided by the fourth embodiment of the present disclosure.

### DETAILED DESCRIPTION OF THE DISCLOSURE

Various embodiments of the present disclosure will be described in more detail below with reference to the accompanying drawings. In each drawing, the same elements are represented by the same or similar reference numerals. For clarity, the various parts in the accompanying drawings are not drawn to scale. In addition, some well-known parts may not be shown.

It should be understood that in the following description, "circuit" refers to a conductive circuit composed of at least one component or sub-circuit through electrical or electromagnetic connections. When a component or circuit is "connected" to another component or "connected" between two nodes, it can be directly coupled or connected to another component or there can be an intermediate component, and the connection between components can be physical, logical, or a combination thereof. On the contrary, when a component is referred to as "directly coupled to" or "directly connected to" another component, it means that there is no intermediate component between the two.

The present disclosure can be presented in various forms, and some examples will be described below.

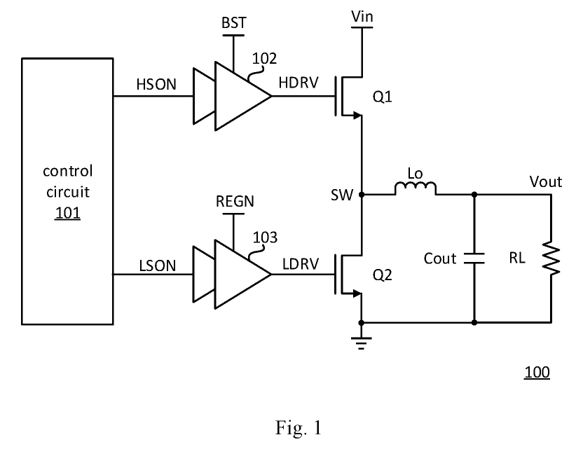

FIG. 1 is a schematic circuit diagram of an existing power transistor driving circuit for a switching power supply, using the driving circuit applied to a Buck converter as an example for illustration. As shown in FIG. 1, the switching power supply 100 comprises a power transistor Q1 (also known as a high side transistor), a power transistor Q2 (also known as a low side transistor), an inductor Lo, an output capacitor Cout, a load resistor RL, a control circuit 101, a driving circuit 102, and a driving circuit 103.

Wherein, the high side transistor Q1 and the low side transistor Q2 are sequentially connected between the input voltage Vin and the ground GND, and their common terminal forms a switching node SW. The first end of the inductor Lo is connected to the switching node SW, and the second end is connected to the output voltage Vout. The output capacitor Cout and the load resistor RL are connected between the output voltage Vout and the ground GND.

The control circuit 101 regulates the high and low level pulse width of the PWM (Pulse Width Modulation) signal by feeding back the difference between the output voltage Vout information and the preset value, and then generates control signals HSON and LSON for the upper and lower transistors based on the PWM signal. In order to ensure that the high side transistor Q1 and the low side transistor Q2 do not connect simultaneously, which would generate a large current, a certain dead time needs to be set between the switch control signals HSON and LSON to ensure that the high side transistor Q1 will only turn on after the low side transistor Q2 is turned off; finally, the switch control signals HSON and LSON pass through the upper and lower transistor driving circuits 102 and 103, respectively, to generate the gate driving signal HDRV for driving the high side transistor Q1 and the gate driving signal LDRV for driving the low side transistor Q2, so as to control the on or off of the high side transistor Q1 and the low side transistor Q2, so that energy is transmitted to the output terminal through Vin to the switching node SW and maintain the stability of the output voltage Vout.

Although NMOS power transistors require bootstrap capacitors, they have higher driving efficiency and smaller device size than PMOS power transistors, and are therefore often used as power switch transistors in switching power supply systems. The existing power transistor driving technology generally adopts a totem pole structure, which uses upper and lower driving transistors connected between the power rail voltage domain BST-SW to drive the power transistor. At the moment when the lower driving transistor is turned off, the upper driving transistor charges the gate capacitor (including gate source capacitor and gate drain capacitor) of the power transistor (such as the high side transistor Q1) with its maximum current capacity, causing the power transistor to conduct quickly. During the conduction process of the power transistor, its drain source current rises sharply, that is, di/dt is large. A large di/dt will increase the voltage stress of the low side transistor Q2, reduce circuit stability, and slow down the conduction time of the high side transistor, which will increase the switching loss of the power transistor and reduce the efficiency of the switching power supply. Therefore, there is still a lot of room for improving the existing driving technology of power transistors.

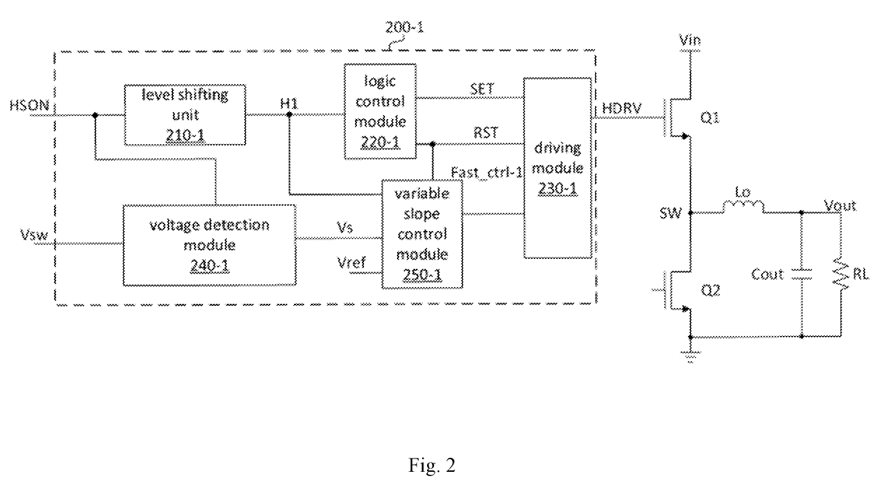

FIG. 2 is a schematic structural diagram of a power transistor driving circuit for a switching power supply provided in the first embodiment of the present disclosure. Take the driving circuit applied to Buck converter as an example, the switching power supply comprises power transistor Q1 (also known as high side transistor), power transistor Q2 (also known as low side transistor), inductor Lo, output capacitor Cout, load resistor RL, and power transistor driving circuit 200-1.

Wherein, the high side transistor Q1 and the low side transistor Q2 are sequentially connected between the input voltage Vin and the ground GND, and their common terminal forms a switching node SW. The first end of the inductor Lo is connected to the switching node SW, and the second end is connected to the output voltage Vout. The output capacitor Cout and the load resistor RL are connected between the output voltage Vout and the ground GND.

It should be understood that in this embodiment, transistor Q1 is the main power transistor, and transistor Q2 is the rectifier transistor. Transistors Q1 and Q2 can be any type of field-effect transistors, such as metal oxide semiconductor field-effect transistors (MOSFETs), and within the scope taught by the present disclosure, they can also be other types of field-effect transistors and/or other types of transistors known to those skilled in the art.

In an exemplary embodiment, power transistors Q1 and Q2 can be implemented by NMOS transistors, with the drain of power transistor Q1 connected to input voltage Vin, the source of power transistor Q1 and the drain of power transistor Q2 connected to switching node SW, and the source of power transistor Q2 connected to the ground.

The power transistor driving circuit 200-1 of the embodiment of the present disclosure is used to generate the gate driving signal HDRV of the power transistor Q1 according to the switch control signal HSON, so as to control the on and off of the power transistor Q1. Schematically, when the switch control signal HSON is turned high (e.g. high level), the power transistor Q1 is turned on (i.e. the power transistor is turned on), and when the switch control signal HSON is turned low (e.g. low level), the power transistor Q1 is turned off (i.e. the power transistor is turned off).

Furthermore, the power transistor driving circuit 200-1 comprises a level shifting unit 210-1, a logic control module 220-1, a driving module 230-1, a voltage detection module 240-1, and a variable slope control module 250-1.

Wherein, the level shifting unit 210-1 is used to boost the switch control signal HSON in the low power rail voltage domain to the high power rail voltage domain, where the low power rail voltage domain is from the low power supply voltage VDD to the ground level GND, and the high power rail voltage domain is from the bootstrap voltage BST in the switching power supply to the switching node SW.

The logic control module 220-1 is used to generate the conduction control signal SET and the off control signal RST based on the boosted switch control signal H1.

The driving module 230-1 is used to generate the gate driving signal HDRV for driving the power transistor Q1 based on the on control signal SET and the off control signal RST. Furthermore, during the process that the power transistor Q1 is turned on, the gate driving signal HDRV has multiple slopes that are time-dependent. Schematically, when the power transistor Q1 is turned on, the gate driving signal HDRV has a first slope in the first time period and a second slope in the second time period thereafter, and the first slope is greater than the second slope; thus, it is possible to ensure that the gate voltage of the power transistor can quickly reach the Miller platform voltage during the first time period when the power transistor is conducting, and to rapidly reduce the channel current of the rectifier transistor. In addition, the conduction speed can be reduced during the second time period after the power transistor crosses the Miller platform voltage, in order to reduce the resonance peak voltage of the voltage at the switching node and lower the voltage stress of the low side transistor Q2. Though the driving delay of the power transistor is increased in the second time period, the increased conduction loss of the circuit is also minimal due to the small channel current at this time.

The voltage detection module 240-1 is connected to the switching node SW and is used to detect the voltage at the switching node Vsw when the power transistor Q1 is turned on, so as to obtain a voltage detection signal Vs that represents the voltage at the switching node Vsw.

The variable slope control module 250-1 is used to compare the voltage detection signal Vs with the reference voltage Vref in each switching cycle and provide a fast conduction control signal Fast_ctrl-1 to the driving module 230-1 in the next switching cycle based on the obtained comparison signal, so as to adjust the duration of the first time period in the next switching cycle. Furthermore, the variable slope control module 250-1 is used to reduce the duration of the first time period in the next switching cycle when the voltage detection signal Vs is greater than the reference voltage Vref, and to increase the duration of the first time period in the next switching cycle when the voltage detection signal Vs is less than the reference voltage.

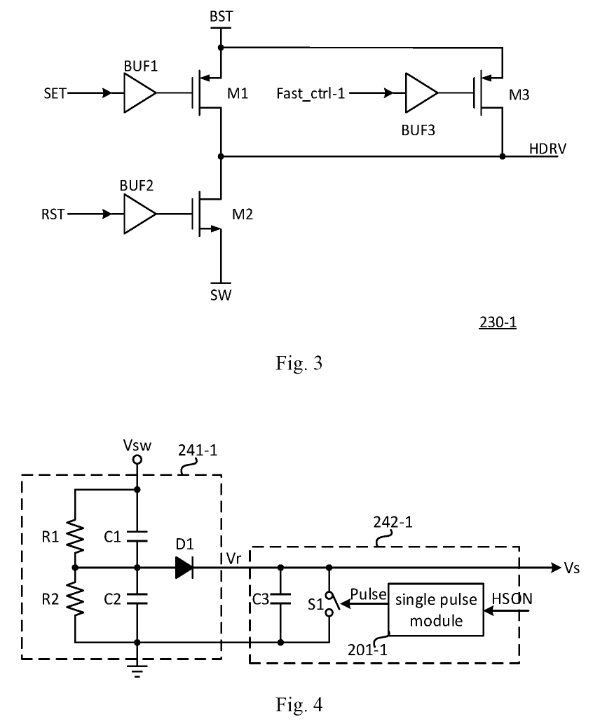

FIG. 3 is a schematic circuit diagram of the driving module provided in the first embodiment of the present disclosure. As shown in FIG. 3, the driving module 230-1 of this embodiment comprises pull-up transistors M1 and M3, pull-down transistor M2, and buffers BUF1 to BUF3. Wherein, the pull-up transistor M1 and the pull-down transistor M2 are connected between the high-power rail voltage domain BST-SW, with their intermediate nodes connected to the gate driving signal HDRV. The first end of the pull-up transistor M3 is connected to the bootstrap voltage BST of the switching power supply, and the second end is connected to the gate driving signal HDRV. The input terminal of buffer BUF1 is connected to the conduction control signal SET, and the output terminal is connected to the control terminal of pull-up transistor M1. The input terminal of buffer BUF2 is connected to the off-control signal RST, and the output terminal is connected to the control terminal of pull-down transistor M2. The input terminal of buffer BUF3 is connected to the fast conduction control signal Fast_ctrl-1, and the output terminal is connected to the control terminal of pull-down transistor M3.

Exemplarily, in this embodiment, the pull-up transistors M1 and M3 are, e.g., PMOS transistors, and the pull-down transistor M2 is an NMOS transistor. When the switch control signal HSON is at a low level, the off control signal RST is valid (e.g. high level) and the conduction control signal SET and the fast conduction control signal Fast_ctrl-1 are invalid (e.g., high level). The pull-down transistor M2 is turned on and the pull-up transistors M1 and M3 are turned off. The gate driving signal HDRV is pulled down by the pull-down transistor M2 to turn off the power transistor Q1. When the switch control signal HSON is at high level, the off control signal RST is invalid (e.g. low level), and thus the pull-down transistor M2 is turned off, and during the first time period of the conduction process of the power transistor Q1, the conduction control signal SET and the fast conduction control signal Fast_ctrl-1 are both valid (e.g. low level), so the pull-up transistors M1 and M3 are both turned on, increasing the gate pull-up impedance of the power transistor Q1, thereby causing the gate driving signal HDRV to rise with a larger slope; in the second time period thereafter, the conduction control signal SET is valid and the fast conduction control signal Fast_ctrl-1 is invalid, so the pull-up transistor M1 is turned on and the pull-up transistor M3 is turned off, thereby reducing the gate pull-up impedance of the power transistor Q1 and causing the gate driving signal HDRV to rise at a smaller slope.

FIG. 4 is a schematic circuit diagram of the voltage detection module according to the first embodiment of the present disclosure. As shown in FIG. 4, the voltage detection module 240-1 of this embodiment comprises a voltage sampling unit 241-1 and a peak detection unit 242-1.

Wherein, the voltage sampling unit 241-1 is connected to the voltage at the switching node Vsw to generate a voltage sampling signal Vr representing the voltage at the switching node Vsw. Furthermore, the voltage sampling unit 241-1 comprises resistors R1 and R2, capacitors C1 and C2, and diode D1. Wherein, the first end of resistor R1 is connected to the voltage at the switching node Vsw, the second end of resistor R1 is connected to the first end of resistor R2, and the second end of resistor R2 is connected to the ground. The first end of capacitor C1 is connected to the voltage at the switching node Vsw; the second end of capacitor C1 is connected to the first end of capacitor C2; the second end of capacitor C2 is connected to ground; the anode of diode D1 is connected to the intermediate node between resistors R1 and R2, and the intermediate node between capacitor C1 and capacitor C2, and the cathode is used to output the voltage sampling signal Vr.

The peak detection unit 242-1 is used to sample the voltage sampling signal Vr according to the switch control signal HSON, to generate a voltage detection signal Vs representing the peak value of the voltage sampling signal Vr. Furthermore, the peak detection unit 242-1 comprises a capacitor C3, a switch S1, and a single pulse module 201-1. Wherein, the first end of capacitor C3 is connected to the cathode of diode D1, which is the output terminal of voltage sampling unit 241-1. Switch S1 is connected between the two ends of capacitor C3. Single pulse module 201-1 is used to output a single pulse signal Pulse with a fixed duration when the rising edge of switch control signal HSON is detected. Exemplarily, the on and off of the switch S1 are controlled by the single pulse signal Pulse. When the single pulse signal Pulse is in an invalid state (e.g. low level), the switch S1 is turned off, and the voltage sampling signal Vr charges the capacitor C3; when the single pulse signal Pulse is in an active state (e.g. high level), the switch S1 is turned on, and the capacitor C3 discharges to the ground through the switch S1, and then the voltage detection signal Vs is obtained at the first end of the capacitor C3.

Furthermore, the working principle of the voltage detection module 240-1 in this embodiment is that when the switch control signal HSON flips to the high level, the switch S1 is turned on for a certain period of time, thereby resetting the voltage on the capacitor C3 to zero. As the power transistor Q1 begins to conduct, the voltage waveform at the switching node SW is converted into a proportional voltage Vr by the high-speed capacitor voltage divider composed of capacitors C1 and C2, and then the peak value of the voltage Vr is stored on the capacitor C2 to obtain the voltage detection signal Vs.

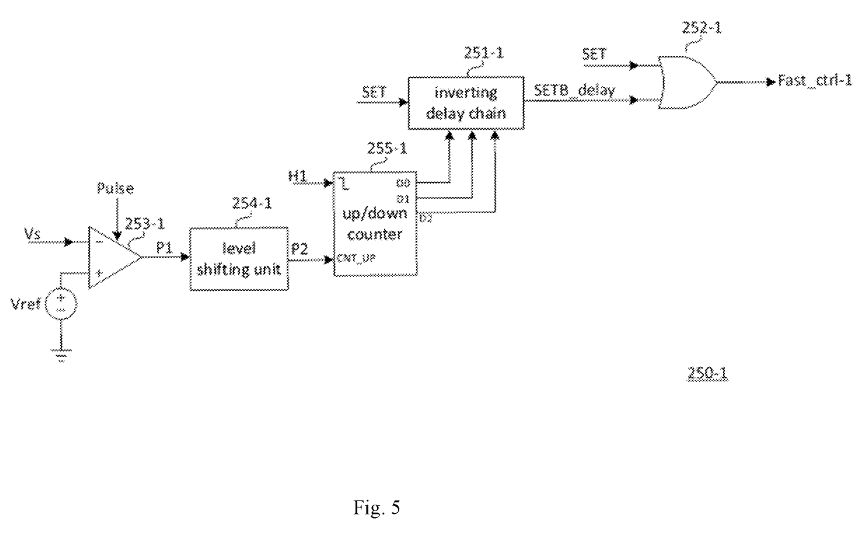

FIG. 5 is a schematic circuit diagram of the variable slope control module according to the first embodiment of the present disclosure. As shown in FIG. 5, the variable slope control module 250-1 of this embodiment comprises an inverting delay chain 251-1, an OR gate 252-1, a comparator 253-1, a level shifting unit 254-1, and an up/down counter 255-1.

Wherein, the inverting delay chain 251-1 is used to generate the inversed delay signal SETB_delay of the conduction control signal SET, and the invalid edge (e.g. rising edge) of the inversed delay signal SETB_delay is delayed by the first time period relative to the valid edge (e.g. falling edge) of the conduction control signal SET.

Schematically, the inverting delay chain 251-1 can be composed of multiple identical or similar delay units cascaded together. These delay units are typically implemented based on various physical principles, such as the charging and discharging characteristics of RC circuits composed of capacitors and resistors, the propagation delay characteristics of transmission lines, or the switching delay of transistors. Each delay unit generates a fixed, small delay on the input signal, and when the signal passes through these delay units in sequence, the accumulated delay is equal to the sum of the delay times of each delay unit. By using digital control to select the path or stage through which the signal passes in the delay unit array, different delay amounts can be achieved. For example, if the inverting delay chain 251-1 has 8 delay units, if the signal chooses to pass through only 4 of them, the signal will receive 4 times the delay time of a single unit. If the signal chooses to pass through only 3 of them, the signal will receive 3 times the delay time of the single delay unit.

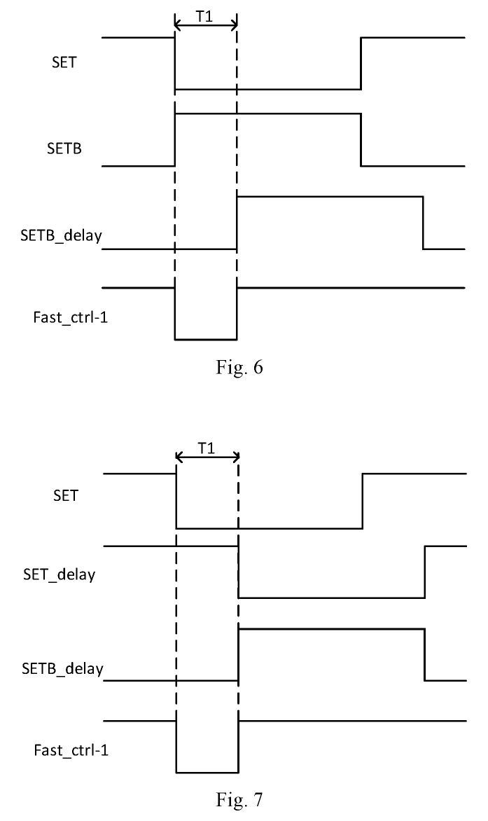

FIG. 6 is a working waveform diagram of the inverting delay chain provided in the first embodiment of the present disclosure. As shown in FIG. 6, in an exemplary implementation, the inverting delay chain 251-1 can first obtain the inverse signal SETB of the conduction control signal SET, then delay the signal SETB for a time period T1,and finally obtain the inversed delay signal SETB_delay.

FIG. 7 is another working waveform diagram of the inverting delay chain provided in the first embodiment of the present disclosure. As shown in FIG. 7, in another exemplary implementation, the inverting delay chain 251-1 can first obtain the delay signal SET_delay of the conduction control signal SET and then invert the signal SET_delay to finally obtain the inversed delay signal SETB_delay.

Continue to refer to FIG. 5, OR gate 252-1 is used to perform OR logic operation on the conduction control signal SET and the inversed delay signal SETB_delay to generate the fast conduction control signal Fast_ctrl-1. As shown in FIGS. 6 and 7, the valid level (e.g. low level) time of the fast conduction control signal Fast_ctrl-1 in this embodiment is equal to the delay time of the reverse delay signal SETB_delay relative to the conduction control signal. Therefore, the valid level time of the fast conduction control signal Fast_ctrl-1in each switching cycle can be adjusted by digitally controlling the path or stage of the conduction control signal SET in the reverse delay chain 251-1 and then adjusting the duration of the first slope of the gate driving signal in each switching cycle.

The negative input terminal of comparator 253-1 is used to receive the voltage detection signal Vs, and the positive input terminal is used to receive the reference voltage Vref. The comparator 253-1 is used to compare the voltage detection signal Vs with the reference voltage Vref to generate a comparison signal P1 at the output terminal. Schematically, when the voltage detection signal Vs is greater than the reference voltage Vref, the comparison signal P1 is at low level; when the voltage detection signal Vs is less than the reference voltage Vref, the comparison signal P1 is at high level.

Furthermore, the comparator 253-1 is a comparator with latch function, which is used to compare the voltage detection signal Vs with the reference voltage Vref when the single pulse signal Pulse is in an active state (e.g. high level), and to latch the comparison result when the single pulse signal Pulse is in an inactive state (e.g. low level), until the next active single pulse signal arrives, at which point the comparator 253-1 will make comparison again. It should be noted that the present disclosure does not limit this, and those skilled in the art can use other structures of comparator circuits to implement the comparator 253-1 according to specific situations.

The level shifting unit 254-1 is used to boost the comparison signal P1 in the low power rail voltage domain to the comparison signal P2 in the high-power rail voltage domain.

The up-down counter 255-1 has a clock terminal, a control terminal, and an output terminal. The clock terminal of the up-down counter 255-1 is used to receive the switch control signal H1, and the control terminal of the up-down counter 255-1 is used to receive the boosted comparison signal P2. The output terminal of the up-down counter 255-1 is connected to the enable control terminal of the inverting delay chain 251-1. The addition and subtraction counter 255-1 is used to perform addition and subtraction operations based on the level state of the comparison signal P2 and the pulse edge of the switch control signal H1, and to control the delay time of the delay chain 251-1 by adjusting the count value of the digital signal.

Furthermore, the addition and subtraction counter 255-1 of this embodiment selects addition or subtraction counting based on the level state of the comparison signal P2. When the comparison signal P2 is at a high level, the counter 255-1 is in the addition counting mode, which counts the falling edge of the switch control signal H1 according to the addition rule. That is, every time a falling edge of the switch control signal H1 is detected, the counter will add 1 to the current count value, thereby increasing the delay time of the reverse delay chain 251-1 by one delay unit. When the comparison signal P2 is at a low level, the counter 255-1 is in subtraction counting mode, which counts the falling edge of the switch control signal H1 according to the subtraction rule. That is, every time a rising edge of the switch control signal H1 is detected, the counter 255-1 will subtract 1 from the current count value (which needs to be non-zero), thereby reducing the delay time of the reverse delay chain 251-1 by one delay unit.

Schematically, the up-down counter 255-1 is a binary counter composed of multiple flip flops cascaded together, and the generated digital signal includes multiple binary digits, such as 3-bit binary digits D0-D2. Furthermore, the addition and subtraction counter 255-1 counts according to the addition and subtraction rules of binary numbers, that is, when in the addition counting mode, the carry output of the low-level flip-flop will be used as the clock input of the high-level flip-flop. When the low-level trigger changes from 1 to 0, a carry signal is generated, triggering the high-level trigger to flip, thereby achieving the addition counting of multi-bit binary numbers; when in subtraction counting mode, when the lowest bit trigger changes from 0 to 1, a borrow signal is generated, causing the high bit trigger to flip and achieve subtraction counting of multi bit binary numbers.

The working principle of the variable slope control module 250-1 in this embodiment is that when the voltage detection signal Vs is greater than the reference voltage Vref, the comparison signals P1 and P2 are at low level, indicating that the conduction time of the pull-up transistor M3 in the current switching cycle is too long. Therefore, when the rising edge of the switch control signal H1 in the next switching cycle arrives, the up-down counter 255-1 will subtract 1 from the current count value, thereby reducing the delay time of the inverting delay chain 251-1 by one delay unit in the next switching cycle. When the voltage detection signal Vs is less than the reference voltage Vref, the comparison signals P1 and P2 are at high level, indicating that the conduction time of the pull-down transistor M3 in the current switching cycle is too short. Therefore, when the rising edge of the switch control signal H1 in the next switching cycle arrives, the up-down counter 255-1 will add 1 to the current count value, thereby increasing the delay time of the inverting delay chain 251-1 by one delay unit in the next switching cycle.

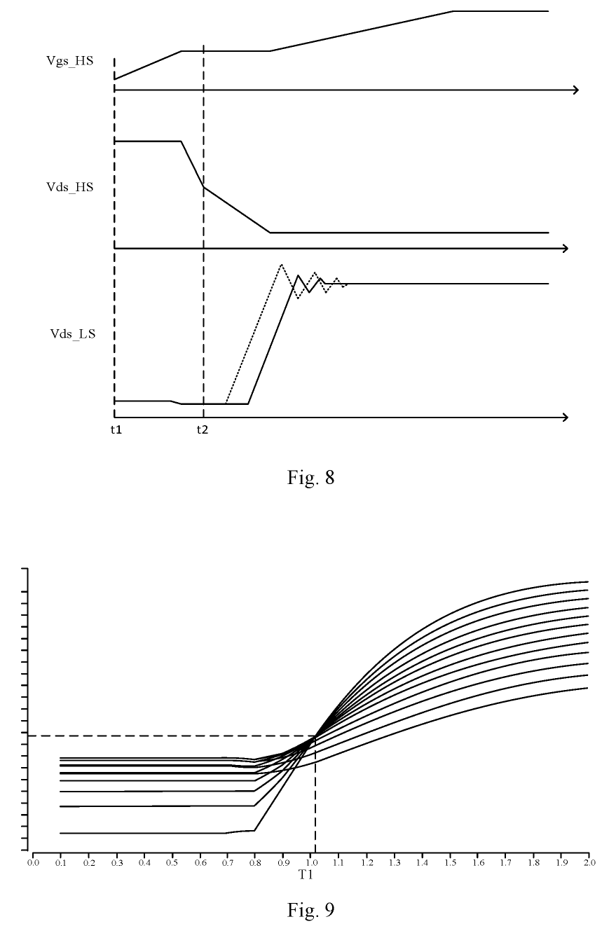

FIG. 8 is a working waveform of the power transistor driving circuit provided in the first embodiment of the present disclosure. In FIG. 3, Vgs_HS represents the gate voltage of the high side transistor Q1, Vds_HS represents the drain source voltage of the high side transistor Q1, and Vds_LS represents the drain source voltage of the low side transistor Q2. As shown in FIG. 8, during the time periodt1-t2, both pull-up transistors M1 and M3 are turned on, increasing the gate pull-up impedance of high side transistor Q1, thereby increasing the pull-up slope of the gate driving signal HDRV. This allows the gate voltage Vgs of high side transistor Q1 to rise to the Miller platform voltage, achieving the goal of shortening the drive delay. After time t2, the pull-up transistor M1 is turned on and the pull-up transistor M3 is turned off, reducing the pull-up impedance of the power transistor Q1, thereby reducing the pull-up slope of the gate driving signal HDRV, reducing the resonance peak voltage and voltage stress of the low side transistor Q2, and improving the reliability of the device. Although the driving delay of the high side transistor Q1 increases after time t2, the increased off loss of the circuit is also small due to the small channel current Id at this time.

FIG. 9 is a schematic diagram of the relationship between the fast slope conduction time T1 and the peak voltage at the switching node during the process of the load current changing from 10A to 120A in the power transistor driving circuit when the input voltage Vin is 16V provided by the first embodiment of the present disclosure. As shown in FIG. 9, the power transistor driving circuit of the embodiment of the present disclosure can ensure the stability of the voltage peak of the switching node in different load current application scenarios by adjusting the fast slope conduction time T1, while reducing the voltage stress on the low side transistor and improving the reliability of the circuit.

It should be noted that although the high side transistor in the switching power supply is used as an example to illustrate in the above embodiments, the power transistor driving circuit of the present disclosure is also applicable to the low side transistor of the switching power supply. The power rail and voltage detection module used for driving the low side transistor need to correspond to the low side transistor Q2. Therefore, the power transistor driving circuit of the embodiments of the present disclosure is applicable to synchronous rectification architectures integrated within various power transistor segments, including Buck, Boost, and Buck Boost.

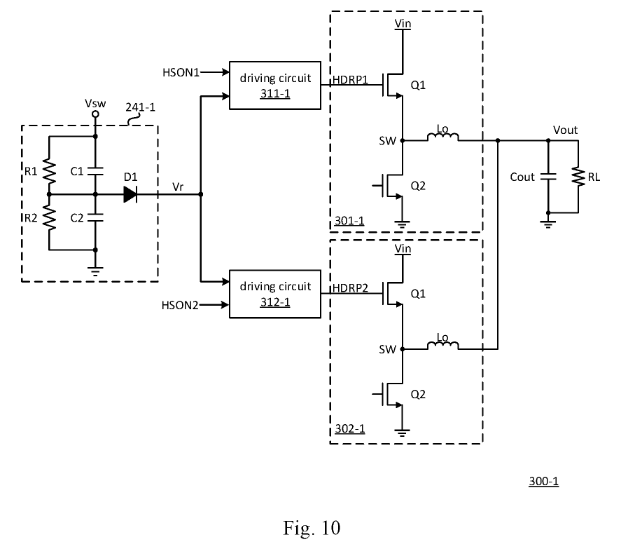

FIG. 10 is a schematic structural diagram of a multi-phase power supply provided in the second embodiment of the present disclosure. Although the single-phase switching power supply is taken as an example in the above embodiments to illustrate the power transistor driving circuit of the present disclosure, it can be understood that the power transistor driving circuit provided by the present disclosure embodiments is also applicable to multi-phase switching power supplies. As shown in FIG. 10, the multi-phase switching power supply 300-1 of this embodiment comprises a parallel multi-phase power stage circuit 301-1, 302-1 (taking a two-phase multi-phase power supply as an example in FIG. 110), multiple driving circuits 311-1, 312-1, and a voltage sampling unit 241-1. For ease of explanation, the structure of the multi-phase power supply controller and feedback circuit is not shown in FIG. 10.

Each power stage circuit comprises a high side transistor Q1, a low side transistor Q2, and an inductor Lo, wherein the drain of the high side transistor Q1 is connected to the input voltage Vin, the source of the high side transistor Q1 is connected to the drain of the low side transistor Q2 and the switching node SW, the source of the low side transistor Q2 is connected to the ground, the first end of the inductor Lo is connected to the switching node, and the second end is connected to the output terminal of the multiphase power supply 300-1. The output capacitor Cout is set between the output terminal and the ground terminal of the multiphase power supply 300-1 to generate an output voltage Vout at both ends. The driving circuits 311-1 and 312-1 can be implemented through the power transistor driving circuit 200-1 in the first embodiment, each receiving switch control signals HSON1 and HSON2 provided by the multiphase power controller, and generating corresponding gate driving signals HDRP1 and HDRP2 for the high side transistor Q1 in the power stage circuit based on the received switch control signals HSON1 and HSON2, to control the on and off of the high side transistor Q1 in the corresponding power stage circuit.

In further embodiments, the voltage sampling unit 241-1 of the power transistor driving circuit 200-1 in the first embodiment can be set outside the driving circuits 311-1 and 312-1, and the driving circuits 311-1 and 312-1 multiplex the voltage sampling unit 241-1 in a time-division manner to reduce the number of passive components in the circuit and reduce the chip area.

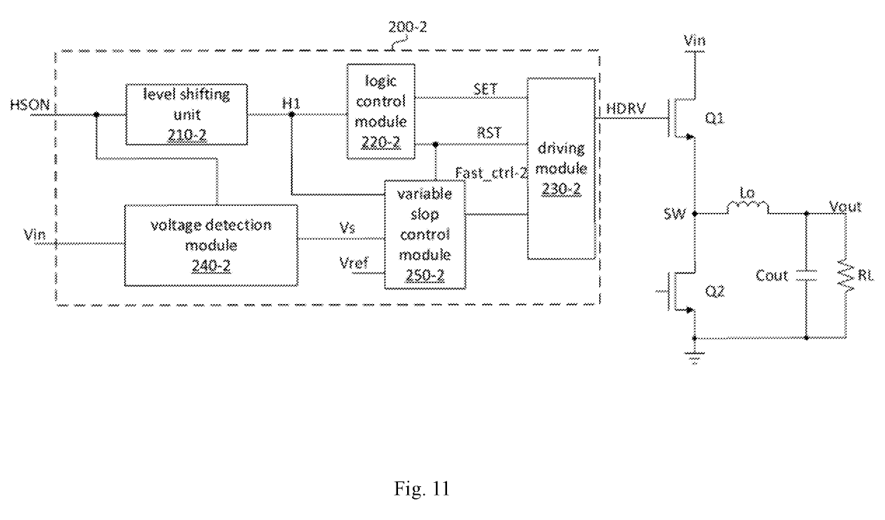

FIG. 11 is a schematic structural diagram of a power transistor driving circuit for a switching power supply provided in the third embodiment of the present disclosure. Take the driving circuit applied to the Buck converter as an example, the switching power supply comprises a power transistor Q1 (also known as a high side transistor), a power transistor Q2 (also known as a low side transistor), an inductor Lo, an output capacitor Cout, a load resistor RL, and a power transistor driving circuit 200-2.

Wherein, the high side transistor Q1 and the low side transistor Q2 are sequentially connected between the input voltage Vin and the ground GND, and their common terminal forms a switching node SW. The first end of the inductor Lo is connected to the switching node SW, and the second end is connected to the output voltage Vout. The output capacitor Cout and the load resistor RL are connected between the output voltage Vout and the ground GND.

It should be understood that in this embodiment, transistor Q1 is the main power transistor, and transistor Q2 is the rectifier transistor. Transistors Q1 and Q2 can be any type of field-effect transistors, such as metal oxide semiconductor field-effect transistors (MOSFETs), and within the scope taught by the present disclosure, they can also be other types of field-effect transistors and/or other types of transistors known to those skilled in the art.

In an exemplary embodiment, power transistors Q1 and Q2 can be implemented through NMOS transistors, with the drain of power transistor Q1 connected to input voltage Vin, the source of power transistor Q1 and the drain of power transistor Q2 connected to switching node SW, and the source of power transistor Q2 connected to the ground.

The power transistor driving circuit 200-2 of the present embodiment is used to generate the gate driving signal HDRV of the power transistor Q1 according to the switch control signal HSON, so as to control the on and off of the power transistor Q1. Schematically, when the switch control signal HSON is turned high (e.g., high level), the power transistor Q1 is turned on (i.e., the power transistor is turned on), and when the switch control signal HSON is turned low (e.g., low level), the power transistor Q1 is turned off (i.e., the power transistor is turned off).

Furthermore, the power transistor driving circuit comprises a level shifting unit 210-2, a logic control module 220-2, a driving module 230-2, a voltage detection module 240-2, and a variable slope control module 250-2.

Wherein, the level shifting unit 210-2 is used to boost the switch control signal HSON in the low power rail voltage domain to the high power rail voltage domain, wherein the low power rail voltage domain is from the low power supply voltage VDD to the ground level GND, and the high power rail voltage domain is from the bootstrap voltage BST in the switching power supply to the switching node SW.

The logic control module 220-2 is used to generate the conduction control signal SET and the off control signal RST based on the boosted switch control signal H1.

The driving module 230-2 is used to generate the gate driving signal HDRV for driving the power transistor Q1 based on the conduction control signal SET and the off control signal RST. Furthermore, during the process of turning off the power transistor Q1, the gate driving signal HDRV has multiple time-dependent slopes. Schematically, when the power transistor Q1 is turned off, the gate driving signal HDRV has a first slope in the first time period and a second slope in the second time period thereafter, and the first slope is greater than the second slope, so as to ensure that its gate voltage can quickly reach the Miller plateau voltage during the first time period when the power transistor is turned off and cause the channel current to rapidly decrease, and to reduce the off speed during the second time period after the power transistor crosses the Miller plateau voltage to reduce voltage stress in the power transistor. Although the driving delay of the power transistor is increased in the second time period, the increased off loss of the circuit was also minimal due to the small channel current at this time.

The voltage detection module 240-2 is connected to the input voltage Vin and the drain of the power transistor Q1 and is used to detect the drain source voltage of the power transistor Q1 when it is turned off, in order to obtain a voltage detection signal Vs that represents the slope of the drain source voltage change of the power transistor Q1.

The variable slope control module 250-2 is used to compare the voltage detection signal Vs with the reference voltage Vref in each switching cycle and provide a fast off control signal Fast_ctrl-2 to the driving module 230-2 in the next switching cycle based on the obtained comparison signal, so as to adjust the duration of the first time period in the next switching cycle. Furthermore, the variable slope control module 250-2 is used to reduce the duration of the first time period in the next switching cycle when the voltage detection signal Vs is greater than the reference voltage Vref, and to increase the duration of the first time period in the next switching cycle when the voltage detection signal Vs is less than the reference voltage.

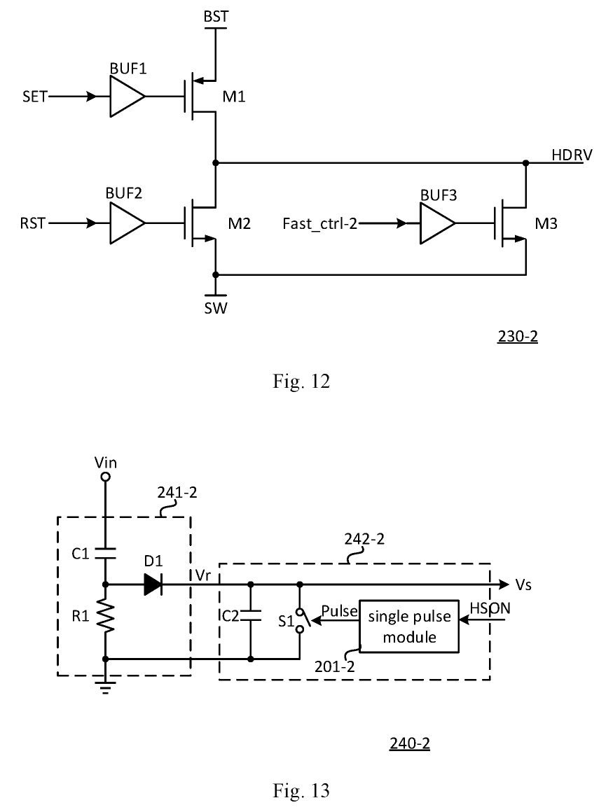

FIG. 12 is a schematic circuit diagram of a driving module provided in the third embodiment of the present disclosure. As shown in FIG. 12, the driving module 230-2 of this embodiment comprises a pull-up transistor M1, pull-down transistors M2 and M3, and buffers BUF1 to BUF3. Wherein, the pull-up transistor M1 and the pull-down transistor M2 are connected between the high-power rail voltage domain BST-SW, and their intermediate nodes are connected to the gate driving signal HDRV. The first end of the pull-down transistor M3 is connected to the gate driving signal HDRV, and the second end is connected to the switching node SW. The input terminal of buffer BUF1 is connected to the conduction control signal SET, and the output terminal is connected to the control terminal of pull-up transistor M1. The input terminal of buffer BUF2 is connected to the off control signal RST, and the output terminal is connected to the control terminal of pull-down transistor M2. The input terminal of buffer BUF3 is connected to the fast off control signal Fast_ctrl-2, and the output terminal is connected to the control terminal of pull-down transistor M3.

For example, the pull-up transistor M1 in this embodiment is, e.g., a PMOS transistor, while the pull-down transistors M2 and M3 are NMOS transistors. When the switch control signal HSON is high level, the conduction control signal SET is valid (e.g. low level) and the off control signal RST and the fast off control signal Fast_ctrl-2 are invalid (e.g. low level), the pull-up transistor M1 is turned on and the pull-down transistors M2 and M3 are turned off, and the gate driving signal HDRV is pulled high by the pull-up transistor M1 to turn on the power transistor Q1. When the switch control signal HSON is at low level, the conduction control signal SET is invalid (e.g. high level), so the pull-up transistor M1 is turned off, and during the first time period of the off process of the power transistor Q1, the off control signal RST and the fast off control signal Fast_ctrl-2 are both valid (e.g. high level), so that both the pull-down transistors M2 and M3 are turned on, increasing the gate pull-down impedance of the power transistor Q1, thereby causing the gate driving signal HDRV to decrease with a larger slope; in the second time period thereafter, the off control signal RST is valid and the off control signal Fast_ctrl-2 is invalid. Therefore, the pull-down transistor M2 is turned on and the pull-down transistor M3 is turned off, thereby reducing the gate pull-down impedance of the power transistor Q1 and causing the gate driving signal HDRV to decrease at a smaller slope.

FIG. 13 is a schematic circuit diagram of a voltage detection module according to a third embodiment of the present disclosure. As shown in FIG. 13, the voltage detection module 240-2 of this embodiment comprises a voltage sampling unit 241-2 and a peak detection unit 242-2.

Wherein, the voltage sampling unit 241-2 is connected to the drain of the power transistor Q1 to generate a voltage sampling signal Vr representing the slope of the drain source voltage change of the power transistor Q1. Furthermore, the voltage sampling unit 241-2 comprises a differential circuit composed of a resistor R1 and a capacitor C1, as well as a diode D1. Wherein, the first end of the capacitor C1 is connected to the input voltage Vin and the drain of the power transistor Q1, the second end is connected to the first end of the resistor R1, the second end of the resistor R1 is connected to the ground, the anode of the diode D1 is connected to the intermediate node between the capacitor C1 and the resistor R1, and the cathode is used to output the voltage sampling signal V.

The peak detection unit 242-2 is used to sample the voltage sampling signal Vr according to the switch control signal HSON, to generate a voltage detection signal Vs representing the peak value of the voltage sampling signal Vr. Furthermore, the peak detection unit 242-2 comprises a capacitor C2, a switch S1, and a single pulse module 201-2. Wherein, the first end of capacitor C2 is connected to the cathode of diode D1, which is the output terminal of voltage sampling unit 241-2. Switch S1 is connected between the two ends of capacitor C2. Single pulse module 201-2 is used to output a single pulse signal Pulse with a fixed duration when the falling edge of switch control signal HSON is detected. Schematically, the conduction and off of the switch S1 are controlled by the single pulse signal Pulse. When the single pulse signal Pulse is in an invalid state (e.g. low level), the switch S1 is turned off, and the voltage sampling signal Vr charges the capacitor C2; when the single pulse signal Pulse is in an active state (e.g. high level), the switch S1 is turned on, and the capacitor C2 discharges to the ground through the switch S1, and then obtains the voltage detection signal Vs at the first end of the capacitor C2.

Furthermore, the working principle of the voltage detection module 240-2 in this embodiment is that: when the switch control signal HSON flips to a low level, the switch S1 is turned on for a certain period of time, thereby resetting the voltage on the capacitor C2 to zero. As the power transistor Q1 starts to turn off, the slope of the drain source voltage change of the power transistor Q1 is converted into a proportional voltage Vr on the resistor R1 by the differential circuit composed of the capacitor C1 and the resistor R1, and then the peak value of the voltage Vr is stored on the capacitor C2 to obtain the voltage detection signal Vs.

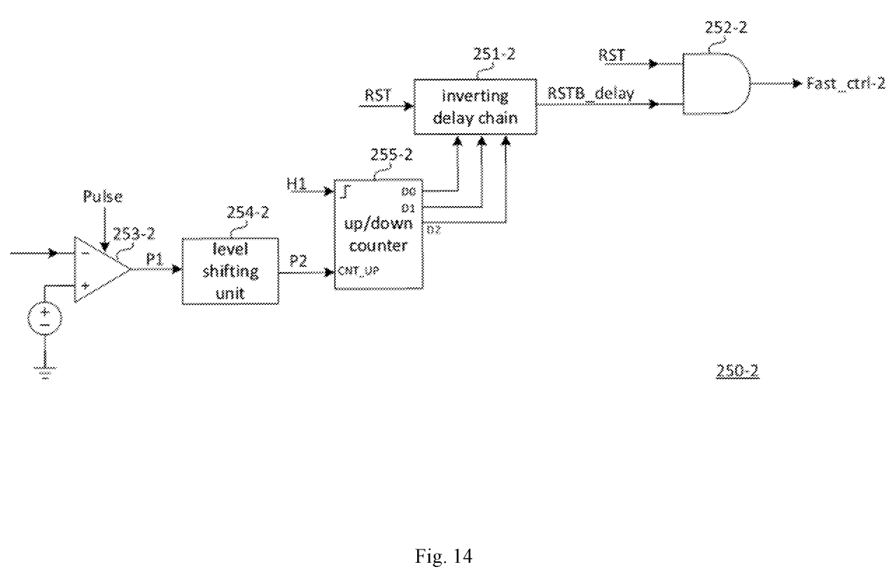

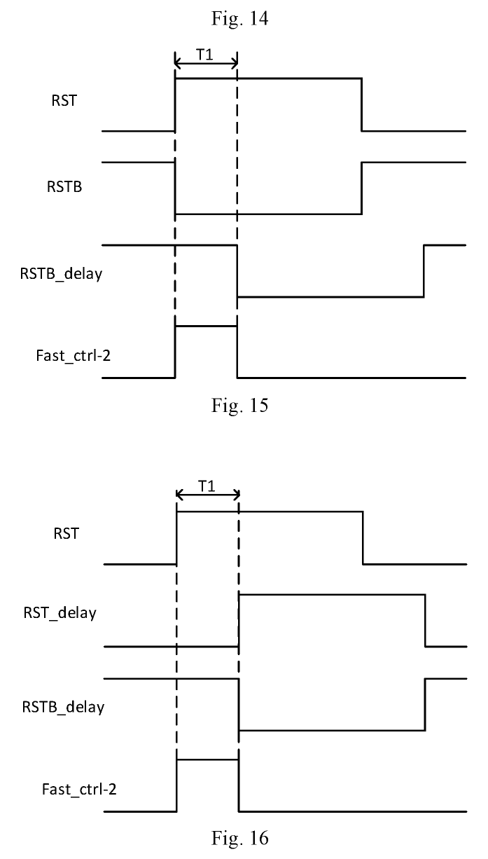

FIG. 14 is a schematic circuit diagram of a variable slope control module according to a third embodiment of the present disclosure. As shown in FIG. 14, the variable slope control module 250-2 of this embodiment comprises an inverting delay chain 251-2, an AND gate 252-2, a comparator 253-2, a level shifting unit 254-2, and an up-down counter 255-2.

Wherein, the inverting delay chain 251-2 is used to generate the inversed delay signal RSTB_delay of the off control signal RST, and the invalid edge (such as the falling edge) of the inversed delay signal RSTB_delay is delayed by the first time period relative to the valid edge (such as the rising edge) of the off control signal.

Schematically, the inverting delay chain 251-2 can be composed of multiple identical or similar delay units cascaded together. These delay units are typically implemented based on various physical principles, such as the charging and discharging characteristics of RC circuits composed of capacitors and resistors, the propagation delay characteristics of transmission lines, or the switching delay of transistors. Each delay unit generates a fixed, small delay on the input signal, and when the signal passes through these delay units in sequence, the accumulated delay is equal to the sum of the delay time of each delay unit. By using digital control to select the number of path or stage through which the signal passes in the delay unit array, different delay amounts can be achieved. For example, if the inverting delay chain 251-2 has 8 delay units, if the signal chooses to pass through only 4 of them, the signal will receive 4 times the delay time of a single unit. If the signal chooses to pass through only 3 of them, the signal will receive 3 times the delay time of a single delay unit.

FIG. 15 is a working waveform diagram of the inverting delay chain provided by the third embodiment of the present disclosure. As shown in FIG. 15, in an exemplary implementation, the inverting delay chain 251-2 can first obtain the inverse signal RSTB of the off control signal RST, then delay the signal RSTB for a time period T1, and finally obtain the inversed delay signal RSTB_delay.

FIG. 16 is another working waveform diagram of the inverting delay chain provided by the third embodiment of the present disclosure. As shown in FIG. 16, in another exemplary implementation, the inverting delay chain 251-2 can first obtain the delay signal RST_delay of the off control signal RST and then invert the signal RST_delay to finally obtain the inversed delay signal RSTB_delay.

Continue to refer to FIG. 14, AND gate 252-2 is used to perform AND logic operation on the off control signal RST and the inverted delay signal RSTB_delay to generate the fast off control signal Fast_ctrl-2. As shown in FIGS. 15 and 16, the valid level (e.g. high level) time of the fast off control signal Fast_ctrl-2 in this embodiment is equal to the delay time of the reverse phase delay signal RSTB_delay relative to the off control signal. Therefore, the valid level time of the fast off control signal Fast_ctrl-2 in each switching cycle can be adjusted by digitally controlling the path or stage of the off control signal RST in the reverse phase delay chain 251-2 and then adjusting the duration of the first slope of the gate driving signal in each switching cycle.

The negative input terminal of comparator 253-2 is used to receive the voltage detection signal Vs, and the positive input terminal is used to receive the reference voltage Vref. The comparator 253-2 is used to compare the voltage detection signal Vs with the reference voltage Vref to generate a comparison signal P1 at the output terminal. Schematically, when the voltage detection signal Vs is greater than the reference voltage Vref, the comparison signal P1 is at low level; when the voltage detection signal Vs is less than the reference voltage Vref, the comparison signal P1 is at high level.

Furthermore, the comparator 253-2 is a comparator with latch function, which is used to compare the voltage detection signal Vs with the reference voltage Vref when the single pulse signal Pulse is in an active state (e.g., high level), and to latch the comparison result when the single pulse signal Pulse is in an inactive state (e.g. low level), until the next active single pulse signal arrives, at which point the comparator 253-2 will make comparison again. It should be noted that the present disclosure does not limit this, and those skilled in the art can use other structures of comparator circuits to implement the comparator 253-2 according to specific situations.

The level shifting unit 254-2 is used to boost the comparison signal P1 in the low power rail voltage domain to the comparison signal P2 in the high-power rail voltage domain.

The up-down counter 255-2 has a clock terminal, a control terminal, and an output terminal. The clock terminal of the up-down counter 255-2 is used to receive the switch control signal H1, and the control terminal of the up-down counter 255-2 is used to receive the boosted comparison signal P2. The output terminal of the up-down counter 255-2 is connected to the enable control terminal of the inverting delay chain 251-2. The addition and subtraction counter 255-2 is used to perform addition and subtraction operations based on the level state of the comparison signal P2 and the pulse edge of the switch control signal H1, and to control the delay time of the delay chain 251-2 by adjusting the count value of the digital signal.

Furthermore, the addition and subtraction counter 255-2 of this embodiment selects addition or subtraction counting based on the level state of the comparison signal P2. When the comparison signal P2 is at high level, the counter 255-2 is in addition counting mode, which counts the rising edge of the switch control signal H1 according to the addition rule. That is, every time a rising edge of the switch control signal H1 is detected, the counter will add 1 to the current count value, thereby increasing the delay time of the reverse delay chain 251-2 by one delay unit. When the comparison signal P2 is at low level, the counter 255-2 is in subtraction counting mode, which counts the rising edge of the switch control signal H1 according to the subtraction rule. That is, for each rising edge of the switch control signal H1 detected, the counter 255-2 will subtract 1 from the current count value (which needs to be non-zero), thereby reducing the delay time of the reverse delay chain 251-2 by one delay unit.

Schematically, the addition and subtraction counter 255-2 is a binary counter composed of multiple flip flops cascaded together, and the generated digital signal comprises multiple binary digits, such as 3-bit binary digits D0-D2. Furthermore, the addition and subtraction counter 255-2 counts according to the addition and subtraction rules of binary numbers, that is, when in addition counting mode, the carry output of the low-level flip-flop will be used as the clock input of the high-level flip-flop. When the low-level trigger changes from 1 to 0, a carry signal is generated, triggering the high-level trigger to flip, thereby achieving the addition counting of multi bit binary numbers; when in subtraction counting mode, when the lowest bit trigger changes from 0 to 1, a borrow signal is generated, causing the high bit trigger to flip and achieve subtraction counting of multi bit binary numbers.

The working principle of the variable slope control module 250-2 in this embodiment is that when the voltage detection signal Vs is greater than the reference voltage Vref, the comparison signals P1 and P2 are at low level, indicating that the conduction time of the pull-down transistor M3 in the current switching cycle is too long. Therefore, when the rising edge of the switch control signal H1 in the next switching cycle arrives, the up-down counter 255-2 will subtract 1 from the current count value, thereby reducing the delay time of the inverting delay chain 251-2 by one delay unit in the next switching cycle. When the voltage detection signal Vs is less than the reference voltage Vref, the comparison signals P1 and P2 are high, indicating that the conduction time of the pull-down transistor M3 in the current switching cycle is too short. Therefore, when the rising edge of the switch control signal H1 in the next switching cycle arrives, the up-down counter 255-2 will add 1 to the current count value, thereby increasing the delay time of the inverting delay chain 251-2 by one delay unit in the next switching cycle.

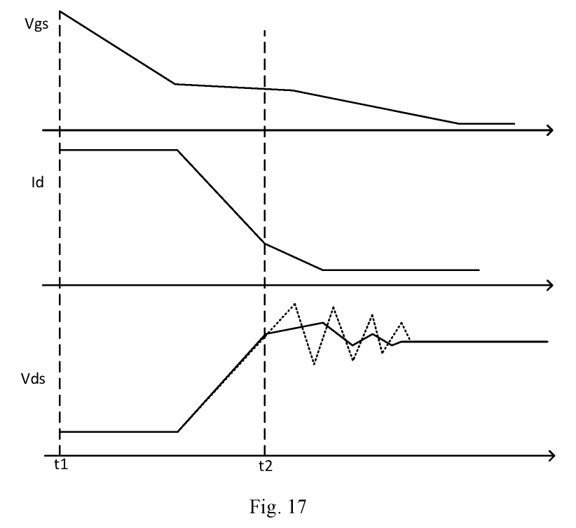

FIG. 17 is a waveform diagram of the power transistor driving circuit provided in the third embodiment of the present disclosure. In FIG. 12, Vgs represents the gate voltage of power transistor Q1, Vds represents the drain source voltage of power transistor Q1, and Id represents the channel current of power transistor Q1. As shown in FIG. 17, during the time period t1-t2, both pull-down transistors M2 and M3 are turned on, increasing the gate pull-down impedance of power transistor Q1, thereby increasing the pull-down slope of the gate driving signal HDRV. This allows the gate voltage Vgs of power transistor Q1 to quickly drop to the Miller platform voltage, achieving the goal of shortening the driving delay. After time t2, the pull-down transistor M2 is turned on and the pull-down transistor M3 is turned off, reducing the pull-down impedance of the power transistor Q1, thereby reducing the pull-down slope of the gate driving signal HDRV, reducing the peak drain source voltage Vds and voltage stress of the power transistor Q1, and improving device reliability. Although the driving delay of the power transistor Q1 increases after time t2, the increased off loss of the circuit is also small due to the small channel current Id at this time.

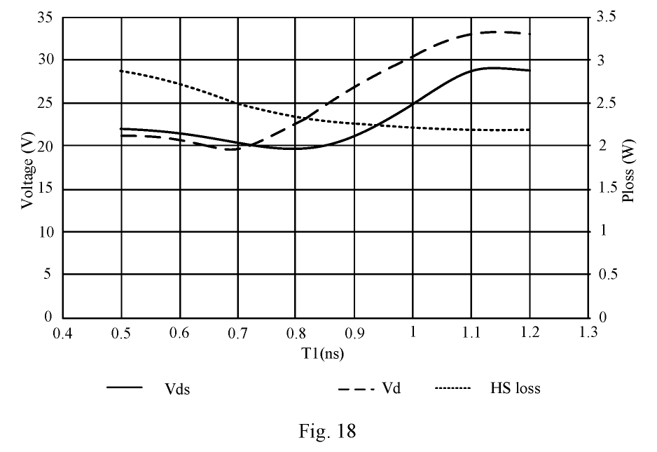

FIG. 18 is a schematic diagram of the relationship between the fast slope off duration of the power transistor driving circuit provided by the third embodiment of the present disclosure and the voltage of each node and the off loss of the high side transistor in the switching power supply. As shown in FIG. 18, the longer the fast slope off time T1 in each switching cycle, the higher the drain voltage Vd and drain source voltage Vds of the high side transistor Q1; that is, the higher the voltage stress of the high side transistor Q1 during the off process of each switching cycle, the smaller the off loss of the high side transistor Q1. The power transistor driving circuit 200-2 of the present embodiment detects the drain source voltage of the power transistor Q1 in each switching cycle through a negative feedback loop and controls the fast slope off duration of the power transistor Q1 in the next switching cycle based on the detection result, thereby solving the balance relationship between switch loss and voltage stress caused by off delay.

It should be noted that although the high side transistor in the switching power supply is used as an example in the above embodiments, the power transistor driving circuit of the embodiments of the present disclosure is also applicable to the low side transistor of the switching power supply. The power rail and voltage detection module used for driving the low side transistor need to correspond to the low side transistor Q2. Therefore, the power transistor driving circuit of the embodiment of the present disclosure is applicable to synchronous rectification architectures integrated within various power tube segments, including Buck, Boost, and Buck Boost.

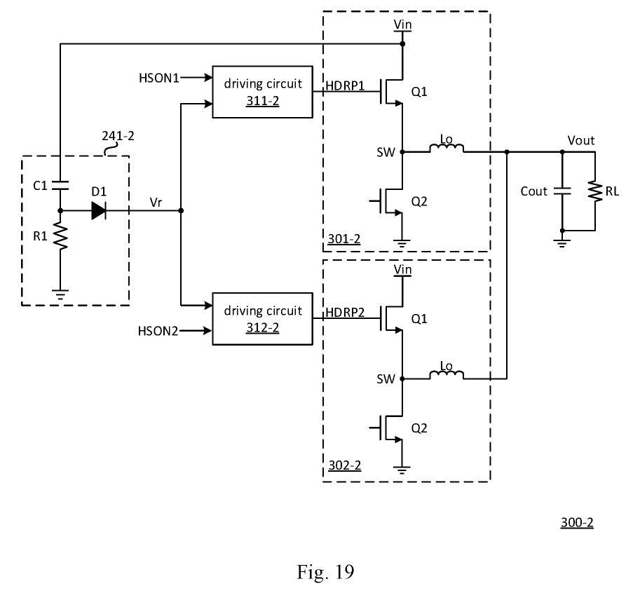

FIG. 19 is a schematic structural diagram of a multi-phase power supply provided in the fourth embodiment of the present disclosure. Although the single-phase switching power supply is taken as an example in the above embodiments to illustrate the power transistor driving circuit of the present disclosure, it can be understood that the power transistor driving circuit provided by the present disclosure embodiments is also applicable to multi-phase switching power supplies. As shown in FIG. 19, the multi-phase switching power supply 300-2 of this embodiment comprises a parallel multi-phase power stage circuit 301-2, 302-2 (take a two-phase multi-phase power supply as an example in FIG. 19), multiple driving circuits 311-2, 312-2, and a voltage sampling unit 241-2. For ease of explanation, the structure of the multi-phase power supply controller and feedback circuit is not shown in FIG. 19.

Each power stage circuit comprises a high side transistor Q1, a low side transistor Q2, and an inductor Lo, wherein the drain of the high side transistor Q1 is connected to the input voltage Vin, the source of the high side transistor Q1 is connected to the drain of the low side transistor Q2 and the switching node SW, the source of the low side transistor Q2 is connected to ground, the first end of the inductor Lo is connected to the switching node, and the second end is connected to the output terminal of the multiphase power supply 300-2. The output capacitor Cout is set between the output terminal and the ground terminal of the multiphase power supply 300-2 to generate an output voltage Vout at both ends. The driving circuits 311-2 and 312-2 can be implemented through the power transistor driving circuit 200-2 in the third embodiment, each receiving switch control signals HSON1 and HSON2 provided by the multiphase power controller, and generating corresponding gate driving signals HDRV1 and HDRV2 for the high side transistor Q1 in the power stage circuit based on the received switch control signals HSON1 and HSON2, to control the conduction and off of the high side transistor Q1 in the corresponding power stage circuit.

In further embodiments, the voltage sampling unit 241-2 of the power transistor driving circuit 200-2 in the third embodiment can be set outside the driving circuits 311-2 and 312-2 and makes the driving circuits 311-2 and 312-2 to multiplex the voltage sampling unit 241-2 in a time-division manner to reduce the number of passive components in the circuit and reduce the chip area.

It should be understood that although each power stage circuit can be understood with reference to the structures of power stage circuits 301-1 (301-2) and 302-1 (302-2) in FIGS. 10 or 19, and in this embodiment, the inductance of each phase corresponding to each power stage circuit in multiple power stage circuits can be discrete or coupled to each other (for example, the first phase inductance is coupled to the second phase inductance; the third phase inductance is coupled to the fourth phase inductance, and so on). Meanwhile, although the power stage circuit is described as having a Buck topology layout, the technical solution of the present disclosure can be adopted for any type of layout design, such as Boost, Flyback, Buck Boost, Cuk, Sepic, Zeta, etc.

To sum up, the power transistor driving circuit of the present embodiment adopts a variable slope control method to generate the gate driving signal of the power transistor, and detects the waveform of the voltage at the switching node through a negative feedback loop during the conduction process of the power transistor. Based on the detection result, the fast slope duration of the gate driving signal in the next switching cycle is dynamically adjusted, so as to reduce the voltage stress of the low side transistor during the conduction process of the high side transistor without increasing the conduction loss of the power transistor, while balancing high-efficiency driving and circuit reliability.

In the above description, there is no detailed explanation of the well-known structural elements and steps. However, those skilled in the art should understand that the corresponding structural elements and steps can be achieved through various technical measures. In addition, in order to form the same structural elements, those skilled in the art can also design methods that are not completely identical to the methods described above. Furthermore, although each embodiment has been described separately above, it does not mean that the measures in each embodiment cannot be effectively combined.

According to the embodiments of the present disclosure, such as those mentioned above, they do not describe all details, nor are they limited to the specific embodiments of the present disclosure. Obviously, based on the above description, many modifications and changes can be made. This specification selects and specifically describes these embodiments in order to better explain the principles and practical applications of the present disclosure, so that those skilled in the art can make good use of the present disclosure and make modifications based on the present disclosure. The protection scope of the present disclosure shall be subject to the scope defined by the claims of the present disclosure.

What is claimed is:

1. A power transistor driving circuit for a switching power supply, comprising:
a logic control module, for generating a conduction control signal and an off control signal based on a received switch control signal;
a driving module, for generating a gate driving signal for a power transistor based on the conduction control signal and the off control signal, wherein the gate driving signal has a first slope and a second slope which are time-dependent during a conduction process of the power transistor, and the first slope is greater than the second slope;
a voltage detection module, for detecting a voltage at a switching node of the switching power supply upon turn-on of the power transistor, to obtain a voltage detection signal;
a variable slope control module, for comparing the voltage detection signal with a reference voltage and adjusting duration of the first slope of the gate driving signal in a next switching cycle based on a comparison result.

2. The power transistor driving circuit of claim 1, wherein the variable slope control module is configured to reduce the duration of the first slope in the next switching cycle in a case where the voltage detection signal is greater than the reference voltage, and
increase the duration of the first slope in the next switching cycle in a case where the voltage detection signal is less than the reference voltage.

3. The power transistor driving circuit of claim 2, wherein the driving module comprises:
a first pull-up transistor and a pull-down transistor connected between a high power rail voltage domain, wherein a common node of the first pull-up transistor and the pull-down transistor is connected to the gate driving signal;
a second pull-up transistor having a first end connected to a bootstrap voltage of the high power rail voltage domain and a second end connected to the gate driving signal;
a first buffer having an input terminal connected to the conduction control signal and an output terminal connected to a control terminal of the first pull-up transistor;
a second buffer having an input terminal connected to the off control signal and an output terminal connected to a control terminal of the pull-down transistor; and
a third buffer having an input terminal connected to a fast conduction control signal output by the variable slope control module, and an output terminal connected to a control terminal of the second pull-up transistor.

4. The power transistor driving circuit of claim 3, wherein the driving module is configured to turn on the first pull-up transistor and the second pull-up transistor during a first time period that the power transistor is turned on, so that the gate driving signal has the first slope,
and turn on the first pull-up transistor and turn off the second pull-up transistor during a second time period that the power transistor is turned on, so that the gate driving signal has the second slope.

5. The power transistor driving circuit of claim 1, wherein the voltage detection module comprises:
a voltage sampling unit connected to the voltage at the switching node for generating a voltage sampling signal representing the voltage at the switching node; and
a peak detection unit, for generating the voltage detection signal representing a peak value of the voltage sampling signal based on the switch control signal.

6. The power transistor driving circuit of claim 5, wherein the voltage sampling unit comprises:
a first resistor and a second resistor connected between the voltage at the switching node and ground;
a first capacitor and a second capacitor connected between the voltage at the switching node and the ground; and
a diode having an anode connected to an intermediate node between the first resistor and the second resistor, and to an intermediate node between the first capacitor and the second capacitor, and a cathode for outputting the voltage sampling signal;
the peak detection unit comprises:
a third capacitor having a first end connected to the voltage sampling unit and a second end connected to ground; wherein a common node between the third capacitor and the voltage sampling unit is configured to provide the voltage detection signal;
a first switch, connected between two ends of the second capacitor; and
a single pulse module, configured to output a single pulse signal with a fixed duration upon detecting a rising edge of the switch control signal,
wherein, the first switch is turned on upon receiving the single pulse signal, so that the second capacitor discharges to the ground through the first switch.

7. The power transistor driving circuit of claim 3, wherein the variable slope control module comprises:
an inverting delay chain, for generating an inversed delay signal of the conduction control signal based on a received digital signal, wherein an invalid edge of the inversed delay signal is delayed by a set time relative to a valid edge of the conduction control signal;
an OR gate, for performing OR logic operation on the conduction control signal and the inversed delay signal to generate the fast conduction control signal;
a comparator having a negative input terminal for receiving the voltage detection signal, a positive input terminal for receiving the reference voltage, and an output terminal for providing a comparison signal;
a level shifting unit, for boosting the comparison signal in a low power rail voltage domain to the high power rail voltage domain; and
an up-down counter, for performing addition and subtraction operations on the digital signal based on a boosted comparison signal and pulse edges of the switch control signal, so as to adjust the duration of the first slope of the gate driving signal by adjusting a delay time between the inversed delay signal and the conduction control signal.

8. The power transistor driving circuit of claim 7, wherein the comparator is a comparator with a latch function,
wherein, the comparator is configured to compare the voltage detection signal with the reference voltage upon an active state of the single pulse signal, and to latch the comparison result upon an inactive state of the single pulse signal.

9. A power transistor driving circuit for a switching power supply, comprising:
a logic control module, for generating a conduction control signal and an off control signal based on a received switch control signal;
a driving module, for generating a gate driving signal to drive a power transistor based on the conduction control signal and the off control signal, wherein the gate driving signal has a first slope and a second slope that are time-dependent during a process that the power transistor is turned off, and the first slope is greater than the second slope;
a voltage detection module, configured to detect a drain-source voltage of the power transistor upon turn-off of the power transistor, to obtain a voltage detection signal; and
a variable slope control module, configured to compare the voltage detection signal with a reference voltage and adjust duration of the first slope of the gate driving signal in a next switching cycle based on a comparison result.

10. The power transistor driving circuit of claim 9, wherein the variable slope control module is configured to reduce the duration of the first slope in the next switching cycle in a case where the voltage detection signal is greater than the reference voltage, and
increase the duration of the first slope in the next switching cycle in a case where the voltage detection signal is less than the reference voltage.

11. The power transistor driving circuit of claim 10, wherein the driving module comprises:
a pull-up transistor and a first pull-down transistor connected between a high power rail voltage domain, wherein a common node of the pull-up transistor and the first pull-down transistor is connected to the gate driving signal;
a second pull-down transistor having a first terminal connected to the gate driving signal and a second end connected to a switching node of the switching power supply;
a first buffer having an input terminal connected to the conduction control signal and an output terminal connected to a control terminal of the pull-up transistor;
a second buffer having an input end connected to the off control signal and an output end connected to a control terminal of the first pull-down transistor; and
a third buffer having an input end connected to the fast off control signal output by the variable slope control module, and an output end connected to a control terminal of the second pull-down transistor.

12. The power transistor driving circuit of claim 11, wherein the driving module is configured to turn on the first pull-down transistor and the second pull-down transistor during a first time period that the power transistor is turned off, so that the gate driving signal has the first slope,
and turn on the first pull-down transistor and turn off the second pull-down transistor during a second time period that the power transistor is turned off, so that the gate driving signal has the second slope.

13. The power transistor driving circuit of claim 9, wherein the voltage detection module comprises:
a voltage sampling unit, connected to a drain of the power transistor, configured to generate a voltage sampling signal that represents a change slope of the drain-source voltage; and
a peak detection unit, for generating the voltage detection signal that represents a peak value of the voltage sampling signal based on the switch control signal.

14. The power transistor driving circuit of claim 13, wherein the voltage sampling unit comprises:
a first capacitor having a first end connected to the drain of the power transistor;
a first resistor having a first end connected to a second end of the first capacitor and a second end connected to the ground; and
a diode having an anode connected to an intermediate node between the first capacitor and the first resistor, and a cathode for outputting the voltage sampling signal;
the peak detection unit comprises:
a second capacitor having a first end connected to the voltage sampling unit and a second end is connected to ground; wherein a common node between the second capacitor and the voltage sampling unit is configured to provide the voltage detection signal;
a first switch, connected between two ends of the second capacitor; and
a single pulse module, for outputting a single pulse signal with a fixed duration upon detecting a falling edge of the switch control signal,
wherein, the first switch is turned on upon receiving the single pulse signal, so that the second capacitor discharges to the ground through the first switch.

15. The power transistor driving circuit of claim 11, wherein the variable slope control module comprises:
an inverting delay chain, for generating an inversed delay signal of the off control signal based on a received digital signal, wherein an invalid edge of the inversed delay signal is delayed by a set time relative to a valid edge of the off control signal;
an AND gate, for performing AND logic operation on the off control signal and an inverted delay signal to generate a fast off control signal;
a comparator having a negative input end for receiving the voltage detection signal, a positive input end for receiving the reference voltage, and an output terminal for providing a comparison signal;
a level shifting unit, for boosting the comparison signal in a low power rail voltage domain to the high power rail voltage domain; and
an up-down counter, for performing addition and subtraction operations on the digital signal based on a boosted comparison signal and pulse edges of the switch control signal, so as to adjust the duration of the first slope of the gate driving signal by adjusting a delay time between the inversed delay signal and the off control signal.

16. The power transistor driving circuit of claim 15, wherein the comparator is a comparator with a latch function,
wherein, the comparator is configured to compare the voltage detection signal with the reference voltage upon an active state of the single pulse signal, and to latch the comparison result upon an inactive state of the single pulse signal.

17. A switching power supply, comprising:
one or more parallel power stage circuits, each power stage circuit comprising a high side transistor, a low side transistor, and an inductor, wherein the high side transistor and the low side transistor are configured to control charging and discharging of the inductor to control a switching power supply to achieve power transmission; and
one or more power transistor driving circuit of claim 1, wherein each power transistor driving circuit is configured to provide a gate driving signal to the high side transistor of a corresponding power stage circuit to control on and off of the high side transistor.

18. The switching power supply of claim 17, wherein, upon configuration of a plurality of power transistor driving circuits, the plurality of power transistor driving circuits multiplex a voltage sampling unit in the voltage detection module in a time-division manner.
